(19) United States
(12) Patent Application Publication
(10) Pub. No.: US 2026/0163328 A1
(43) Pub. Date: Jun. 11, 2026

(54) OPTICAL AMPLIFIER

(71) Applicants: ASML Netherlands B.V., Veldhoven (NL); Trumpf Lasersystems For Semiconductor Manufacturing SE, Ditzingen (DE)

(72) Inventors: Alexander Matthijs STRUYCKEN, Eindhoven (NL); Joachim SCHULZ, Gerlingen (DE); Steffen Alfred ERHARD, Korntal-Muenchingen (DE)

(73) Assignees: ASML Netherlands B.V., Veldhoven (NL); Trumpf Lasersystems For Semiconductor Manufacturing SE, Ditzingen (DE)

(21) Appl. No.: 19/125,639

(22) PCT Filed: Oct. 11, 2023
(86) PCT No.: PCT/EP2023/078266

§ 371 Date: Apr. 29, 2025

(30) Foreign Application Priority Data
Nov. 4, 2022 (EP) 22205638.4

(51) Int. Cl. H01S 3/23; G03F 7/00; H01S 3/08

(52) U.S. Cl. CPC H01S 3/2325; G03F 7/70033; H01S 3/08059

(57) ABSTRACT

An optical amplifier configured to amplify a laser beam, the optical amplifier comprising: an optical path of the laser beam, the optical path comprising a first part and a second part and a reflector configured to reflect the laser beam so as to direct the laser beam between the first and second parts of the optical path, the reflector being configured to reflect the laser beam such that the laser beam reflected by the reflector is parallel to the laser beam incident on the reflector.

### CROSS-REFERENCE TO RELATED APPLICATIONS

This application claims priority of EP application 22205638.4 which was filed on Nov. 4, 2022 and which is incorporated herein in its entirety by reference.

### FIELD

The present invention relates to an optical amplifier and associated systems.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

A lithographic system may comprise a radiation system and a lithographic apparatus. The radiation system may comprise a laser system configured to generate a laser beam and a EUV radiation source. EUV radiation may be produced, for example, by directing the laser beam into the radiation source so that the laser beam is incident on a fuel in the radiation source. The laser beam may deposit energy into the fuel to create a plasma. Radiation, including EUV radiation, may be emitted from the plasma.

The laser system may comprise a laser configured to generate a laser beam and an optical amplifier configured to amplify the laser beam. In use, the laser beam passing through the optical amplifier may be subject to one or more pointing errors or fluctuations. The pointing errors or fluctuation may cause one or more errors or fluctuations in a laser beam position. These errors or fluctuations may be proportional to an optical path of the laser beam in the optical amplifier. As such, when directing the laser beam through more than one optical amplifier, errors or fluctuations in the laser beam position may increase. The errors or fluctuation in the laser beam position may cause a loss of power of the amplified laser beam.

### SUMMARY

According to a first aspect of the present invention there is provided an optical amplifier configured to amplify a laser beam, the optical amplifier comprising an optical path of the laser beam, the optical path comprising a first part and a second part, and a reflector configured to reflect the laser beam so as to direct the laser beam between the first and second parts of the optical path, the reflector being configured to reflect the laser beam such that the laser beam reflected by the reflector is parallel to the laser beam incident on the reflector.

In use, thermal loads may act on the optical amplifier. For example, thermal loads acting on the optical amplifier may cause movement and/or deformation of one or more parts of the optical amplifier. The movement and/or deformation of the one or more parts of the optical amplifier may be referred to as internal movement and/or deformation. The one or more parts of the optical amplifier may comprise one or more optical elements and/or a frame configured to support the one or more optical elements. The movement or deformation of the one or more parts of the optical amplifier may result in a beam pointing error or beam pointing fluctuations of the laser beam passing through the optical amplifier. The beam pointing error or beam pointing fluctuations of the laser beam may result in a loss of power of an amplified laser beam. By configuring the reflector such that the laser beam reflected by the reflector is parallel to the laser beam incident on the reflector, the beam pointing error or beam pointing fluctuations of the laser beam passing through the optical amplifier may be reduced or prevented. As such, the loss of power of the amplified laser beam may be reduced or prevented.

The reflector may be configured to reflect the laser beam at least two times, e.g. to direct the laser beam between the first and second parts of the optical path.

The reflector may comprise a retroreflector. The retroreflector may comprise at least one of: a corner reflector and/or a conical reflector. The corner reflector may comprise a corner cube.

The reflector may comprise one or more reflective surfaces. The one or more reflective surfaces may comprise a first position, e.g. on or at which the laser beam is incident. The one or more reflective surfaces may comprise a second position, e.g. at which the laser beam is reflected away from the reflector. At least one or each of the one or more reflective surfaces may comprise or define a planar surface or a curved surface. The first and second positions of the one or more reflective surfaces may be spaced from each other. A distance between the first and second positions of the one or more reflective surfaces may correspond to a space between the first and second parts of the optical path. The one or more reflective surfaces may be arranged such that the laser beam is reflected at least three times, e.g. to direct the laser beam between the first and second parts of the optical path. The one or more reflective surfaces may be arranged such that at least one reflective surface is arranged between at least two other reflective surfaces. The one or more reflective surfaces may be arranged such that at least one reflective surface is arranged to face in a first direction. The one or more reflective surfaces may be arranged such that at least one other reflective surface is arranged to face in a second direction. The first and second directions may be different and/or opposite, e.g. substantially opposite, to each other. The one or more reflective surfaces may be arranged such that at least one of: the laser beam reflected by the reflector, the laser beam incident on the reflector and/or a path of the laser beam between the first and second positions of the one or more reflective surfaces define an M-shape.

According to a second aspect of the present invention there is provided an amplifier system for use in a laser system, the system comprising a plurality of optical amplifiers, at least one or each optical amplifier of the plurality of optical amplifier comprising an optical amplifier according to the first aspect, an optical system configured to optically couple at least one of the plurality of optical amplifiers to at least one other of the plurality of optical amplifiers and a frame configured to support the optical system, the frame being configured to be separate from the plurality of optical amplifiers.

In use, thermal loads may act on at least one or each of the plurality of optical amplifiers. For example, thermal loads acting on the at least one or each of the plurality of optical amplifiers may cause movement and/or deformation of one or more parts of the at least one or each of the plurality of optical amplifiers. The one or more parts of the at least one of the plurality of optical amplifiers comprise one or more optical elements and/or a frame configured to support the one or more optical elements. When the optical system, e.g. one or more parts thereof, is connected to each of the plurality of optical amplifiers, movement and/or deformation of the one or more parts of each of the plurality of optical amplifiers may cause movement of the one or more parts of the optical system connected thereto. This movement of the one or more parts of the optical system that are connected to each of the plurality of optical amplifiers may be referred to as external movement. This external movement may result in a beam pointing error or beam pointing fluctuations of an amplifier laser beam, which may be directed to another one of the optical amplifiers or exit the amplifier system. By configuring the frame to be separate from the plurality of optical amplifiers and by configuring the reflector such that the laser beam reflected by the reflector is parallel to the laser beam incident on the reflector, a beam pointing error or beam pointing fluctuations of the amplified laser beam, which may be due to the internal movement and/or deformation and the external movement, may be reduced or prevented. As such, the loss of power of the amplified laser beam may be reduced or prevented.

The frame may be configured to support the optical system such that at least one or each of the plurality of optical amplifiers is moveable relative to the optical system. The frame may be configured to support the optical system such that at least one or each of the plurality of optical amplifiers is detached from the optical system.

The frame may comprise or be formed from at least one of: a metal material, a metal alloy material, a fibrous material, a ceramic material and/or a glass material. The metal material may comprise aluminium. The metal alloy material may comprise at least one of: steel and/or stainless steel. The fibrous material may comprise carbon fibre.

The system may comprise a further frame. The further frame may be configured to mount the plurality of optical amplifiers. The frame may be connected to the further frame. The frame may be integral with the further frame.

According to a third aspect of the present invention there is provided an amplifier system for use in a laser system, the system comprising a plurality of optical amplifiers configured to amplify a laser beam, wherein at least one or each of the plurality of optical amplifiers comprises an optical path of the laser beam, the optical path comprising a first part and a second part, an optical system configured to optically couple at least one of the plurality of optical amplifiers to at least one other of the plurality of optical amplifiers, a frame configured to support the optical system, the frame being configured to be separate from the plurality of optical amplifiers, wherein at least one or each of the plurality of optical amplifiers comprises a retroreflector configured to direct the laser beam between the first and second parts of the optical path.

According to a fourth aspect of the present invention there is provided a laser system comprising a laser configured to generate a laser beam and an amplifier system according to the second and/or third aspects, wherein the amplifier system is configured to amplify the laser beam.

The frame may be configured to connect to the laser, e.g. a housing of the laser.

According to a fifth aspect of the present invention there is provided a radiation system comprising an EUV radiation source and a laser system according to fourth aspect.

According to a sixth aspect of the present invention there is provided a radiation system comprising an EUV radiation source and a laser system comprising an optical amplifier according to the first aspect.

According to a seventh aspect of the present invention there is provided a lithographic system comprising a radiation system according to the fifth aspect and a lithographic system.

Various aspects and features of the invention set out above or below may be combined with various other aspects and features of the invention as will be readily apparent to the skilled person.

### BRIEF DESCRIPTION OF THE DRAWINGS

Embodiments of the invention will now be described, by way of example only, with reference to the accompanying schematic drawings, in which:

FIG. 1 depicts a lithographic system comprising a lithographic apparatus and a radiation system;

FIG. 2 depicts an exemplary amplifier system for use in a laser system of the radiation system of FIG. 1;

FIG. 3 depicts an exemplary optical path of a laser beam through the amplifier system of FIG. 2;

FIG. 4 depicts an exemplary optical amplifier for use in the amplifier system of FIG. 2, wherein the optical amplifier comprises a reflector;

FIG. 5 depicts an exemplary optical path of the laser beam through the optical amplifier of FIG. 4;

FIG. 6 depicts an exemplary amplifier frame for use in the optical amplifier of FIG. 4;

FIG. 7 schematically depicts an exemplary optical path of the laser beam through the optical amplifier of FIG. 4, wherein the reflector comprises a reflection prism;

FIG. 8A depicts a schematic side view of the optical amplifier of FIG. 4, wherein the reflector comprises the reflection prism;

FIG. 8B depicts a schematic plan view of the optical amplifier of FIG. 4, wherein the reflector comprises the reflection prism;

FIG. 9A depicts a schematic side view of the optical amplifier of FIG. 4 and one or more parts of an optical system of the amplifier system of FIG. 1, which are supported on a frame that is separated from the optical amplifier, wherein the reflector comprises the reflection prism;

FIG. 9B depicts a schematic plan view of the optical amplifier of FIG. 4 and one or more parts of an optical system of the amplifier system of FIG. 1, which are supported on the frame that is separate from the optical amplifier, wherein the reflector comprises the reflection prism;

FIG. 10A schematically depicts the optical path of the laser beam through the optical amplifier of FIG. 4 in an x, y plane of FIG. 7, wherein the reflector comprises the reflection prism;

FIG. 10B schematically depicts the optical path of the laser beam through the optical amplifier of FIG. 4 in a y, z plane of FIG. 7, wherein the reflector comprises the reflection prism;

FIG. 11 schematically depicts another exemplary optical path of the laser beam through the optical amplifier of FIG. 4, wherein the reflector comprises a retroreflector;

FIG. 12A depicts a schematic plan and side view of the optical amplifier of FIG. 4, wherein the reflector comprises the retroreflector;

FIG. 12B depicts a schematic plan and side view of the optical amplifier of FIG. 4 and one or more parts of an optical system of the amplifier system of FIG. 1, which are supported on the frame that is separate from the optical amplifier, wherein the reflector comprises the retroreflector;

FIG. 13 schematically depicts the optical path of the laser beam through the optical amplifier of FIG. 4 in the x, y plane and the y, z plane of FIG. 11, wherein the reflector comprises the retroreflector;

FIG. 14A depicts an exterior side of a part of the amplifier system of FIG. 1;

FIG. 14B depicts an interior side of the part of the amplifier system of FIG. 1;

FIG. 14C depicts the part of amplifier system of FIG. 14B including the optical amplifiers;

FIGS. 15A to 15C schematically depict another exemplary reflector for use in the optical amplifier of FIG. 4;

FIG. 16 schematically depicts another exemplary reflector for use in the optical amplifier of FIG. 4; and

FIG. 17 schematically depicts another exemplary reflector for use in the optical amplifier of FIG. 4.

### DETAILED DESCRIPTION

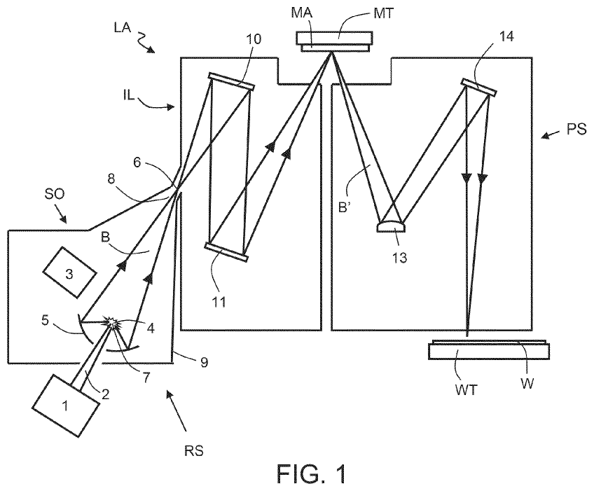

FIG. 1 shows a lithographic system comprising a radiation system RS and a lithographic apparatus LA. The radiation system RS comprises a radiation source SO. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13,14 in FIG. 1, the projection system PS may include a different number of mirrors (e.g., six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO shown in FIG. 1 is, for example, of a type which may be referred to as a laser produced plasma (LPP) source. A laser system 1, which may, for example, include a CO₂ laser, is arranged to deposit energy via a laser beam 2 into a fuel, such as tin (Sn) which is provided from, e.g., a fuel emitter 3. Although tin is referred to in the following description, any suitable fuel may be used. The fuel may, for example, be in liquid form, and may, for example, be a metal or alloy. The fuel emitter 3 may comprise a nozzle configured to direct tin, e.g. in the form of droplets, along a trajectory towards a plasma formation region 4. The laser beam 2 is incident upon the tin at the plasma formation region 4. The deposition of laser energy into the tin creates a tin plasma 7 at the plasma formation region 4. Radiation, including EUV radiation, is emitted from the plasma 7 during de-excitation and recombination of electrons with ions of the plasma.

The EUV radiation from the plasma is collected and focused by a collector 5. Collector 5 comprises, for example, a near-normal incidence radiation collector 5 (sometimes referred to more generally as a normal-incidence radiation collector). The collector 5 may have a multilayer mirror structure, which is arranged to reflect EUV radiation (e.g., EUV radiation having a desired wavelength such as 13.5 nm). The collector 5 may have an ellipsoidal configuration, having two focal points. A first one of the focal points may be at the plasma formation region 4, and a second one of the focal points may be at an intermediate focus 6, as discussed below.

The laser system 1 may be spatially separated from the radiation source SO. Where this is the case, the laser beam 2 may be passed from the laser system 1 to the radiation source SO with the aid of a beam delivery system (not shown) comprising, for example, suitable directing mirrors and/or a beam expander, and/or other optics. The laser system 1, the radiation source SO and the beam delivery system may together be considered to be a radiation system.

Radiation that is reflected by the collector 5 forms the EUV radiation beam B. The EUV radiation beam B is focused at intermediate focus 6 to form an image at the intermediate focus 6 of the plasma present at the plasma formation region 4. The image at the intermediate focus 6 acts as a virtual radiation source for the illumination system IL. The radiation source SO is arranged such that the intermediate focus 6 is located at or near to an opening 8 in an enclosing structure 9 of the radiation source SO.

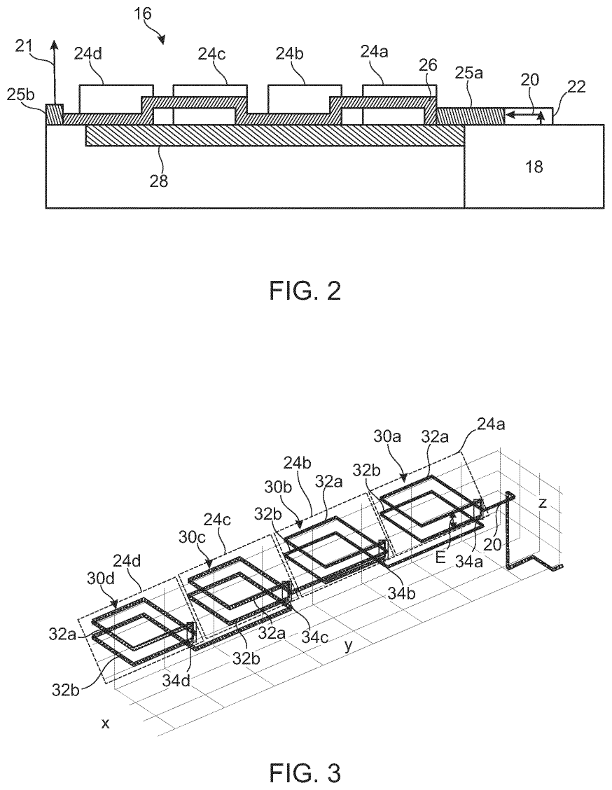

FIG. 2 shows an exemplary amplifier system 16 for use in the laser system 1 of the radiation system RS. The amplifier system 16 may also be referred to as an optical amplifier system. The laser system 1 may comprise a laser 18, such as the CO₂ laser. The laser 18 may be configured to generate a laser beam 20. The laser beam 20 may comprise a plurality of pulses. The laser system 1 may comprise one or more optical elements 22, such as one or more mirrors, beam expanders, lenses and/or other elements, for directing the laser beam into the amplifier system 16.

The amplifier system 16 comprises a plurality of optical amplifiers 24a-24d, four of which are shown in FIG. 2. However, it will be appreciated that in other embodiments, the system may comprise more or less than four optical amplifiers. Each of the optical amplifiers 24a-24d is configured to amplify the laser beam 20.

The amplifier system 16 comprises an optical system 26. The optical system 26 may also be referred to as a relay optical system. The optical system 26 is configured to optically couple or connect at least one of the optical amplifiers 24a-24d to at least one other of the optical amplifiers 24a-24d. In the present embodiment, the optical system 26 is configured to optically couple or connect the amplifiers 24a-24d in series to each other. For example, the optical system 26 may be configured to optically couple or connect the optical amplifiers 24a-24d to each other so that the laser beam 20 is directed from a first amplifier 24a to a second amplifier 24b, from the second amplifier 24b to a third amplifier 24c and from the third amplifier 24c to a fourth amplifier 24d. The optical system 26 may comprise a plurality of optical elements, such as a plurality of mirrors, lenses, telescopes and/or the like. The optical amplifiers 24a-24d may be arranged to sequentially amplify the laser beam 20.

The amplifier system 16 may comprise an input 25a, e.g. at which the laser beam 20 enters the amplifier system 16. The amplifier system 16 may comprise an output 25b, e.g. at which the amplified laser beam 21 exits the amplifier system 16. At the input 25a of the amplifier system 16, the laser beam may have a power between about 100 W and 200 W, such as about 140 W. At the output 25b of the amplifier system 16, the amplified laser beam 21 may have a power between about 25 kW and 50 kW. The amplifier system 16 comprises a frame 28 configured to support the optical system 26. For example, the optical system 26 may be mounted to the frame 28. The frame 28 is configured to be separate from the optical amplifiers 24a-24d. The frame 28 may be configured to support the optical system 26 such that each of optical amplifiers 24a-24d is detached from the optical system 26 and/or moveable relative to the optical system 26. For example, there may be no physical connection between each of the optical amplifiers 24a-24d and the optical system 26. By configuring the frame 28 to be separate from the optical amplifiers 24a-24d, pointing errors or fluctuations of the laser beam 20, which may, for example, be due to thermal deformation of a part of each of the optical amplifiers 24a-24d, may be reduced or prevented.

The frame 28 may be configured to connect to the laser 18, e.g. a housing of the laser. For example, the frame 28 may be configured to extend in a direction parallel, e.g. substantially parallel, to the optical amplifiers 24a-24d. The frame 28 may be configured to extend and connect to the laser 18. The frame 28 may also be configured to support at least a part or all of the input 25a. By configuring the frame 28 to connect to the laser, movement of the laser 18 relative to the optical system 26 may be reduced or prevented. Expressed differently, the optical system 26 and the laser 18 may move in unison. As a result, pointing errors or fluctuations of the laser beam 20 may be reduced or prevented. It will be appreciated that in other embodiments, the frame may be differently configured.

FIG. 3 shows an exemplary optical path of the laser beam 20 through the amplifier system 16 shown in FIG. 2. Each optical amplifier 24a-24d is indicated in FIG. 3 by a dashed box. Each optical amplifier 24a-24d comprises or defines a respective optical path 30a-30d. Each optical path 30a-30d comprises a first part 32a and a second part 32b. The first and second parts 32a, 32b of each optical path 30a-30d may be spaced from each other. For example, the first and second parts 32a, 32b of each optical path 30a-30d may be spaced in a direction perpendicular, e.g. substantially perpendicular, to a plane of each of the first and second parts 32a, 32b. A space E between the first and second parts 32a, 32b is indicated in FIG. 3. In the embodiment shown in FIG. 3, the first part 32a is above the second part 32b. However, it will be appreciated that in other embodiments the first and second parts of each optical path may be differently arranged.

Each amplifier 24a-24d comprises a respective reflector 34a-34d, each of which indicated by a box in FIG. 3. As will be described below in more detail, each reflector 34 is configured to reflect the laser beam 20, for example at least two times, so as to direct the laser beam 20 between the first and second parts 32a, 32b of the respective optical path 30a-30d. For example, each reflector 34a-34d may be configured to direct the laser beam 20 from the first part 32a to the second part 32b or from the second part 32b to the first part 32a of the respective optical path 30a-30d. The first and/or second parts 32a, 32b of each optical path 30a-30d of each optical amplifier 24a-24d may also be referred to as a level.

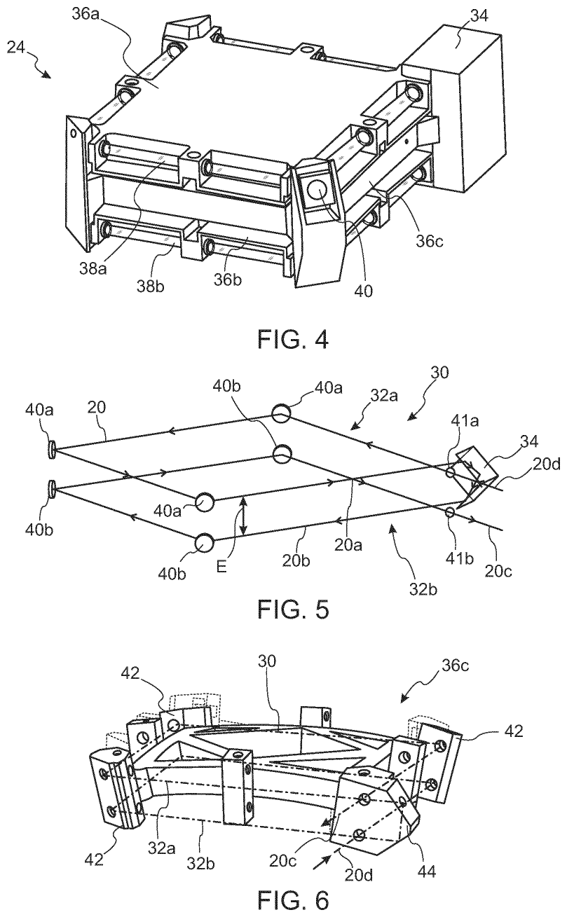

FIG. 4 shows an exemplary optical amplifier 24 for use in the amplifier system 16 shown in FIG. 2. The optical amplifier 24 may comprise a plurality of amplifier frames, such as a first amplifier frame 36a, a second amplifier frame 36b and a third amplifier frame 36c. It will be appreciated that in other embodiments, the optical amplifier may comprise more or less than three amplifier frames. The first amplifier frame 36 may be configured to support a first tubing 38a. The second amplifier frame 36b may be configured to support a second tubing 38b. The first and second tubing 38a, 38b may enclose a gas mixture. In some embodiments, the gas mixture may be sealed in the first and/or second tubing 38a, 38b. In other embodiments, the gas mixture may be pumped, e.g. continuously pumped, through the first and/or second tubing. The gas mixture may comprise carbon dioxide, oxygen, carbon monoxide, nitrogen, hydrogen, xenon and/or helium. The optical amplifier 24 may be configured such that the laser beam 20 is directed through the gas mixture. One or more radiofrequency (RF) signals may be used to excite the molecules of gas mixture. The one or more radiofrequency signals may comprise one or more radiofrequency pulses. Alternatively, the one or more radiofrequency signals may comprise a continuous wave radiofrequency signal. The one or more radiofrequency signals may be applied to the gas mixture to create a population inversion of the molecules of the gas mixture. This may result in amplification of the laser beam 20 passing through the gas mixture.

The amplifier 24 may comprise a plurality of optical elements 40, one of which is indicated in FIG. 4. The optical elements 40 may be provided in the form of one or more reflective elements, such as one or more mirrors. The optical elements 40 may be configured to direct the laser beam 20 through the gas mixture in the first and second tubing 38a, 38b. The optical elements 40 may be arranged at one or more corners of each of the first and second frames 36a, 36b. For example, the optical elements 40 may be arranged at three corners of each of the first and second frames 36a, 36b. The reflector 34 may be arranged at a remaining corner of each of the first and second frames 36a, 36b. The first tubing 38a and some of the optical element 40 may define the first part 32a of the optical path 30 of the amplifier 24. The second tubing 38b and some other of the optical elements 40 may define the second part 32b of the optical path 30 of the amplifier 24. The first tubing 38a may be arranged on a periphery of the first frame 36a. The second tubing 38b may be arranged on a periphery of the second frame 36b.

The third amplifier frame 36c may be configured to support the optical elements 40 and the reflector 34. The third amplifier frame 36c may be arranged between the first and second amplifier frames 36a, 36b.

FIG. 5 shows an exemplary optical path 30 of the laser beam 20 through the optical amplifier 24 shown in FIG. 4. FIG. 6 shows an exemplary third amplifier frame 36c for use in the optical amplifier 24 shown in FIG. 4. The optical path 30 of the laser beam 20 through the optical amplifier 24 is also indicated in FIG. 6 relative to the third amplifier frame 36c by a dashed line.

In this embodiment, each of the first and second parts 32a, 32b of the optical path 30 of the laser beam 20 comprises three optical elements 40. It will be appreciated that in other embodiments, at least one of or each of the first and second paths of the laser beam may comprise more or less than three optical elements. The optical amplifier 24 comprises the reflector 34, which in this embodiment is provided in the form of retroreflector, such as a corner reflector. For example, the corner reflector may be provided in the form of a corner cube. It will be appreciated that in other embodiments, the reflector may be differently implemented. For example, in other embodiments the retroreflector may be provided in the form of a conical reflector, a cat-eye configuration and/or the like.

As can be seen in FIG. 5, the laser beam 20 enters the optical amplifier 24 in proximity to the reflector 34. The optical elements 40 may comprise first optical elements 40a and second optical element 40b. The first optical elements 40a may be arranged to direct the laser beam 20 on the first part 32a of the optical path 30. The first optical elements 40a may be arranged to direct the laser beam 20 onto the reflector 34. The reflector 34 may be configured to reflect the laser beam 20 at least two times, e.g. to direct the laser beam 20 from the first part 32a to the second part 32b of the optical path 30. In this embodiment, the reflector 34 is configured to reflect the laser beam 20 three times, as will be described below in more detail. The reflector 34 is configured to reflect the laser beam 20 such that the laser beam reflected by the reflector 34 is parallel, e.g. substantially parallel, to the laser beam incident on the reflector 34. Expressed differently, a direction of the laser beam reflected by the reflector 34 may be a reversed direction of the laser beam incident on the reflector 34. The laser beam incident on the reflector 34 may also be referred to as an incident laser beam 20a. The laser beam reflected by the reflector 34 may also be referred to as a reflected laser beam 20b. The space E between the first and second parts 32a, 32b of the optical path 30 is indicated in FIG. 5.

The second optical elements 40b may be arranged to direct the laser beam 20 on the second part 32b of the optical path 30. The second optical elements 40b may be arranged to direct the reflected laser beam 20b away from the reflector 34, e.g. so that the reflected laser beam 20b exits the optical amplifier 24 in proximity to the reflector 34. The laser beam that exits the optical amplifier 24 may be considered as an amplified laser beam 20c, e.g. relative to a laser beam 20d that enters the optical amplifier 24. The optical amplifier 24 may comprise a first optical window 41a and a second optical window 41b. The first and second optical windows 41a, 41b may be arranged such that the laser beam 20d enters the optical amplifier 24 through the first optical window 41a and the amplified laser beam 20c exits the optical amplifier through the second optical window 41b.

The third amplifier frame 36c may be configured to support the first and second optical elements 40a, 40b. For example, the third amplifier frame 36c may comprise a plurality of first supporting element 42, three of which are shown in FIG. 6. The first supporting elements 42 may each be provided in the form of block or mounting block. Each first supporting element 42 may be configured to support a first optical element 40a and a second optical element 40b.

The third amplifier frame 36c may be configured to support the reflector 34. For example, the third amplifier frame 36c may comprise a second support element 44. The second supporting element 44 may be provided in the form of block or mounting block. The second supporting element 44 may be configured to support the reflector 34.

The first and second supporting elements 42, 44 may be arranged on one or more corners of the third amplifier frame 36c. For example, the third amplifier frame 36c may define or comprise a rectangular or square shape. The first and second supporting elements 42, 44 may be arranged on one or more corners of the rectangular or square shape.

In use, thermal loads may act on one or more of the first, second and third amplifier frames 36a-36c. For example, thermal loads acting on the third amplifier frame 36c may cause movement and/or deformation, e.g. bending, of at least the third amplifier frame 36c. This may cause movement of the first and/or second supporting element 42, 44, which may cause the first and/or second optical elements 40a, 40b and/or the reflector 34 to become optically misaligned. This may result in one or more drifting and/or pointing errors or fluctuations of the laser beam 20, as will be described below in more detail. The movement and/or deformation of the third amplifier frame 36c is indicated in FIG. 6.

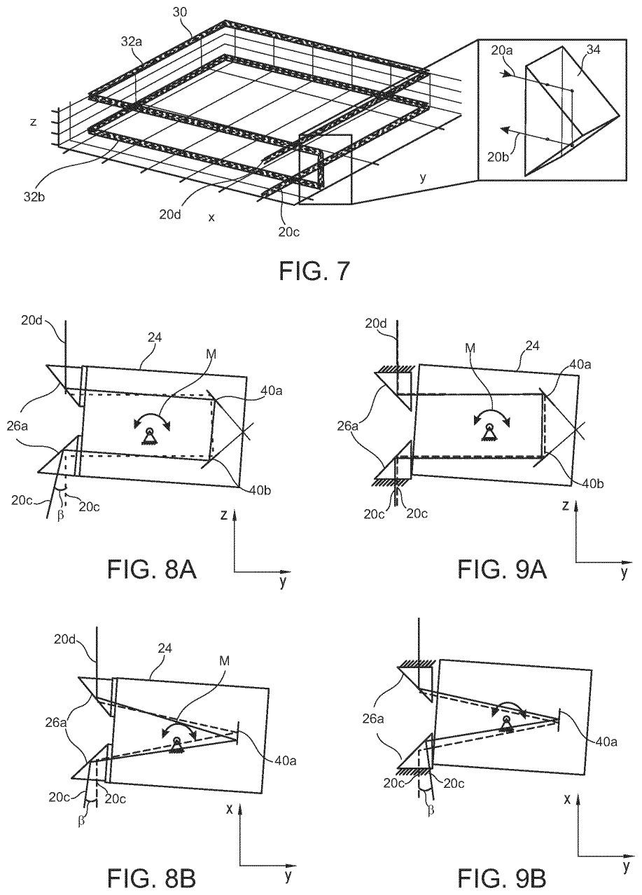

FIG. 7 schematically shows an exemplary optical path 30 of the laser beam 20 through the optical amplifier 24 shown in FIG. 4. The optical path 30 comprises the first and second parts 32a, 32b. In this embodiment, the reflector 34 is provided in the form of a reflection prism, such as a porro prism. FIG. 7 shows the first and second parts 32a, 32b of the optical path 30 relative to a coordinate system.

FIG. 8A shows a schematic side view of the optical amplifier 24 shown in FIG. 4, e.g. in a y, z plane of the coordinate system shown in FIG. 7. FIG. 8B shows a schematic plan view of the optical amplifier 24 shown in FIG. 4, e.g. in an x, y plane of the coordinate system shown in FIG. 7. Only some of the first and second optical elements 40a, 40b are shown in FIGS. 8A and 8B for clarity purposes. The reflector 34 has been omitted from FIGS. 8A and 8B. It will be appreciated that the arrangement of the first and second optical elements 40a, 40b of the optical amplifier 24 shown in FIGS. 8A and 8B is the same as that described above. As described above, the optical amplifier 24 may be configured such that the laser beam 20 enters and exits the optical amplifier 24 at substantially the same location, e.g. in proximity to the reflector 34. However, for the sake of clarity, the laser beam 20 is shown in FIGS. 8A and 8B as entering and exiting the optical amplifier 24 at different locations.

In the example shown in FIGS. 8A and 8B, two parts 26a of the optical system 26 are connected to the optical amplifier 24, e.g. to one or all of the first, second and third amplifier frames 36a to 36c. As the parts 26a of the optical system 26 are connected to the optical amplifier 24, movement and/or deformation of the optical amplifier 24, e.g. the third frame 36c, which is indicated in FIGS. 8A and 8B by the arrow M, may cause movement of the parts 26a of the optical system 26. This may be referred to as external movement and may result in a beam pointing error or beam pointing fluctuations. For example, the amplified laser beam 20c, which is indicated by the solid line in FIGS. 8A and 8B, may exit the optical amplifier 24 at an angle ß relative to an amplified laser beam 20c, when the optical amplifier 24 remains stationary, which is indicated by the dashed line in FIGS. 8A and 8B. The angle of the amplified laser beam 20c may cause a beam pointing error or beam pointing fluctuations. The beam pointing error or beam pointing fluctuations may cause an error or fluctuation of the beam position, which may be proportional to an optical length of the amplifier system 16. As such, with increasing optical length of the amplifier system 16, a beam positioning error or beam positioning fluctuations may increase. The beam pointing error or beam pointing fluctuations may result in a loss of power of the amplified laser beam exiting the optical amplifier, which in turn may result in a loss of power of the amplified laser beam exiting the amplifier system.

FIG. 9A shows a schematic side view of the optical amplifier 24 shown in FIG. 4, e.g. in a y, z plane of the coordinate system shown in FIG. 7. FIG. 9B shows a schematic plan view of the optical amplifier 24 shown in FIG. 4, e.g. in an x, y plane of the coordinate system shown in FIG. 7. FIGS. 9A and 9B are similar to FIGS. 8A and 8B. As such, only difference will be described in the following. In the examples shown in FIGS. 9A and 9B, the optical system 26, e.g. the parts 26a thereof, is supported by the frame 28, as described above. As such, the optical system 26, e.g. the parts 26a thereof, are optically coupled or connected to the optical amplifier 24. However, the optical amplifier 24 is detached from and/or moveable relative to the optical system 26, e.g. the parts 26a thereof. In other words, there is no physical connection between the optical system 26, e.g. the parts 26a thereof, and the optical amplifier 24.

Referring to FIG. 9A, movement and/or deformation of the optical amplifier 24 relative to the optical system 26, e.g. the parts 26a thereof, may result in a shift, such as a translational shift, of the amplified laser beam 20c relative to the amplified laser beam 20c, when the optical amplifier 24 remains stationary. In other words, movement and/or deformation of the optical amplifier 24 may result in the amplified laser beam 20c being parallel, e.g. substantially parallel, relative to the amplified laser beam 20c, when the optical amplifier 24 remains stationary. By configuring the frame 28 to be separate from the optical amplifier 24, pointing errors or fluctuations of the laser beam 20 in at least one plane of the optical amplifier 24, which may be due to the external movement, may be reduced or prevented. In the description above and below, the terms “movement and/or deformation of the optical amplifier 24″ may be considered as encompassing movement and/or deformation of the third frame 36c of the optical amplifier 24. The terms ”movement and/or deformation of the optical amplifier 24″ may also be considered as encompassing movement and/or deformation of the first and/or second frames 36a, 36b of the optical amplifier 24. It will be appreciated that the movement and/or deformation of the optical amplifier 24 may result in an optical misalignment of the optical amplifier 24 relative to the optical system 26, e.g. the parts 26a thereof.

Referring to FIG. 9B, movement and/or deformation of the optical amplifier 24 may cause the amplified laser beam 20c to exit the optical amplifier 24 at an angle β relative to an amplified laser beam 20c, when the optical amplifier 24 remains stationary, in the x, y plane shown in FIG. 7.

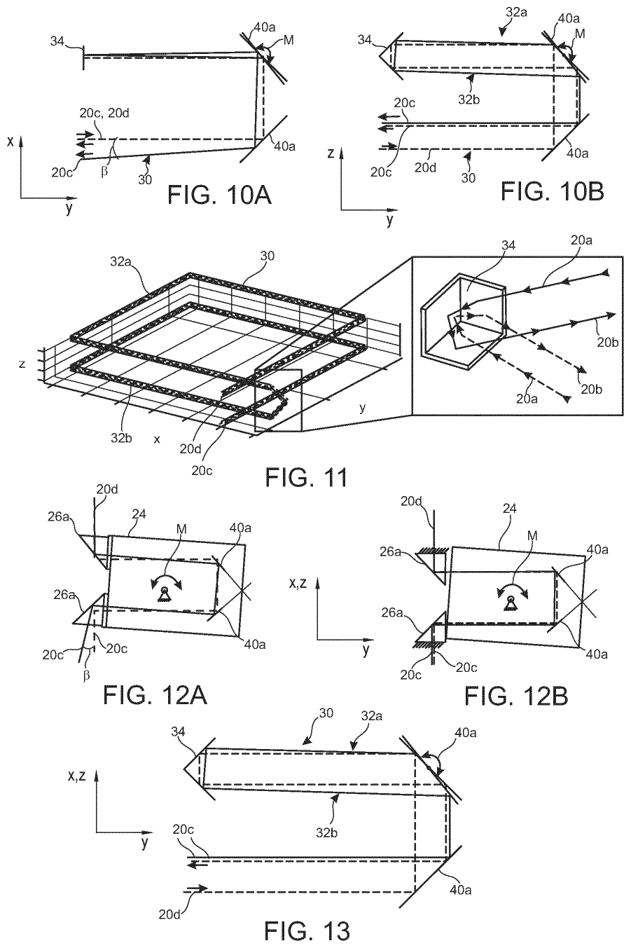

FIG. 10A schematically shows the optical path 30 of the laser beam 20 through the optical amplifier 24 in the x, y plane shown in FIG. 7. FIG. 10B schematically shows the optical path 30 of the laser beam 20 through the optical amplifier 24 in the y, z plane shown in FIG. 7. Only some of the first optical elements 40a are shown in FIGS. 10A and 10B for clarity purposes. However, it will be appreciated that the optical amplifier 24 shown in FIGS. 10A and 10B may comprise the first and second optical elements 40a, 40b, as described above and below. In the examples shown in FIGS. 10A and 10B, one of the first optical elements 40a may move, e.g. due to movement and/or deformation of the optical amplifier 24. This movement and/or deformation may be referred to as internal movement and/or deformation. The movement of the first optical elements 40a is indicated by the arrow M in FIGS. 10A and 10B. It will be appreciated that in other embodiments more than one first optical element and/or one or more of the second optical elements may move, e.g. due to the movement and/or deformation of the optical amplifier. The terms “movement of the first and/or second optical elements” may be considered as encompassing the first and/or second optical elements becoming optically misaligned.

The dashed line in FIGS. 10A and 10B indicates the optical path 30 of the laser beam 20, when the first optical element 40 remains stationary. The solid line in FIG. 10A indicates the optical path 30 of the laser beam 20, when the first optical element 40a has moved. Referring to FIG. 10A, movement of the first optical element 40a may cause the amplified laser beam 20c to exit the optical amplifier 24 at the angle B. In this example, the reflector 34 may be considered as acting as a planar mirror in the in the x, y plane shown in FIG. 7.

Referring to FIG. 10B, movement of the first optical element 40 may cause the amplified laser beam 20c to be shifted, e.g. translationally shifted, and/or parallel, e.g. substantially parallel, relative to the amplified laser beam 20c, when the optical element remains stationary.

FIG. 11 schematically shows another exemplary optical path 30 of the laser beam 20 through the optical amplifier 24 shown in FIG. 4. The optical path 30 comprises the first and second parts 32a, 32b. In this embodiment, the reflector 34 is provided in the form of the retroreflector, e.g. as a corner cube, as described above in relation to the embodiment shown in FIG. 5. It will be appreciated that the reflector may be orientated and/or arranged in a number of ways that are different from those disclosed herein. However, in each of those ways, the reflector may be considered as being configured to reflect the laser beam such that the laser beam reflected by the reflector is parallel to the laser beam incident on the reflector.

FIG. 11 shows the optical path 30 of the laser beam 20 relative to a coordinate system. FIG. 12A shows a schematic plan and side view of the optical amplifier 24 shown in FIG. 4, e.g. in the y, z plane and in the x, y plane of the coordinate system shown in FIG. 11. Only some of the first optical elements 40a are shown in FIG. 12A for clarity purposes. However, it will be appreciated that the optical amplifier 24 shown in FIGS. 10A and 10B may comprise the first and second optical elements 40a, 40b, as described above and below. In the example shown in FIG. 12A, the parts 26a of the optical system 26 are connected to the optical amplifier 24, e.g. to one or all of the first, second and third amplifier frames 36a-36c of the optical amplifier 24. As the parts 26a of the optical system 26 are connected to the optical amplifier 24, movement and/or deformation of the optical amplifier 24, which is indicated in FIG. 12A by the arrow M, may cause movement of the parts 26a of the optical system 26. This may result in a beam pointing error or beam pointing fluctuations. For example, movement and/or deformation of the optical amplifier 24 may cause the amplified laser beam 20c, which is indicated by the solid line in FIG. 12A, to exit the optical amplifier 24 at the angle β relative to the amplified laser beam 20c, when the optical amplifier 24 remains stationary, which is indicated by the dashed line in FIG. 12A.

FIG. 12B shows another schematic plan and side view of the optical amplifier 24 shown in FIG. 4, e.g. in the y, z plane and the x, y plane of the coordinate system shown in FIG. 11. FIG. 12B is similar to FIG. 12A. As such, only differences will be described in the following. In the example shown in FIG. 12B, the optical system 26, e.g. the parts 26a thereof, is supported by the frame 28, as described above. As such, the optical system 26, e.g. the parts 26a thereof, are optically coupled or connected to the optical amplifier 24. However, the optical amplifier 24 is detached from and/or moveable relative to the optical system 26, e.g. the parts 26a thereof. In other words, there is no physical connection between the optical system 26, e.g. the parts 26a thereof, and the optical amplifier 24.

Referring to FIG. 12B, movement and/or deformation of the optical amplifier 24 relative to the optical system 26, e.g. the parts 26a thereof, may result in a shift, e.g. a translational shift, of the amplified laser beam 20c relative to the amplified laser beam 20c, when the optical amplifier 24 remains stationary, in the x, y plane and the y, z plane shown in FIG. 11. As such, a beam point error or fluctuations, which may be due to the external movement, may be reduced or prevented.

FIG. 13 schematically shows the optical path 30 of the laser beam 20 through the optical amplifier 24 shown in FIG. 4 in the x, y plane and the y, z plane shown in FIG. 11. Only some of the first optical elements 40a are shown in FIG. 13 for clarity purposes. However, it will be appreciated that the optical amplifier 24 shown in FIGS. 10A and 10B may comprise the first and second optical elements 40a, 40b, as described above and below. In the example shown in FIG. 13, one of the first optical elements 40a may move, e.g. due to movement and/or deformation of the optical amplifier 24. The movement of the first optical element 40a is indicated by the arrow M in FIG. 13. Although the description of FIGS. 10A, 10B and 13 makes reference to movement of one first optical element 40a, it will be appreciated that in other embodiments, more than one first optical elements and/or one or more second optical elements may move, e.g. due to the movement and/or deformation of the optical amplifier.

The dashed line in FIG. 13 indicates the optical path 30 of the laser beam 20, when the first optical element 40a remains are stationary. The solid line in FIG. 13 indicates the optical path 30 of the laser beam 20, when the first optical element 40a has moved. As can be seen in FIG. 13, movement of the first optical element 40a may cause the amplified laser beam 20c to be shifted, e.g. translationally shifted, and/or parallel, e.g. substantially parallel, relative to the amplified laser beam 20c, when the first optical element 40a remains stationary. By configuring the reflector 34 such that the reflected laser beam 20b is parallel to the incident laser beam 20a, a beam pointing error or beam pointing fluctuations of the laser beam 20 passing through the optical amplifier 24, which may be due to the internal deformation and/or movement, may be reduced or prevented, e.g. in both the x, y plane and the y, z plane. Therefore, by configuring the frame 28 to be separate from the optical amplifier 24 and by configuring the reflector 34 such that the reflected laser beam 20b is parallel to the incident laser beam 20a, a beam pointing error or beam pointing fluctuations of the laser beam 20, which may be due to the internal movement and/or deformation and the external movement, may be reduced or prevented, e.g. in both the x, y plane and the y, z plane of the optical amplifier 24. The x, y plane and y, z plane described above and shown in FIGS. 8A to 13 are used for illustrative purposes only and should not be understood as limiting the features of the optical amplifier to these planes. For example, it will be appreciated that any features described in relation to the y, z, plane of the optical amplifier 24 may also be applicable to an x, z plane of the optical amplifier. As such, by configuring the frame 28 to be separate from the optical amplifier 24 and by configuring the reflector 34 such that the reflected laser beam 20b is parallel to the incident laser beam 20a, the beam pointing error or beam pointing fluctuations of the laser beam 20, which may be due to the internal movement and/or deformation and the external movement, may also be reduced or prevented in the x, z plane of the optical amplifier 24.

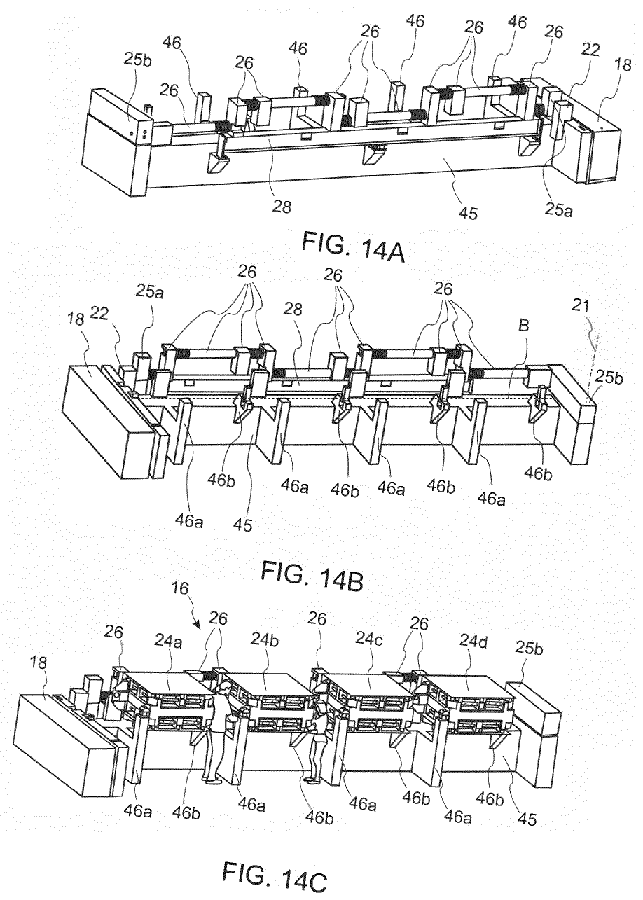

FIGS. 14A and 14B show a part of the amplifier system 16 shown in FIG. 1 without the optical amplifiers 24a-24d. FIG. 14A shows an exterior side of the part of the amplifier system 16 shown in FIG. 1. FIG. 14B shows an interior side of the part of the amplifier system 16.

FIGS. 14A and 14B show the frame 28 that is configured to support the optical system 26. In the embodiment shown in FIGS. 14A and 14B, the frame 28 is not connected to the laser 18. Instead, the frame 28 is configured to only support the optical system 26. However, as described above in relation to FIG. 2, in some embodiments, the frame 28 may be configured to connect to the laser 18.

The frame 28 may be formed from a material, such as a metal material, a metal alloy material, and/or a fibrous material. The material may be selected to be a thermally stable. For example, the metal material may comprise aluminium and/or the like. The metal alloy material may comprise steel, stainless steel and/or the like. The fibrous material may comprise carbon fibre and/or the like. It will be appreciated that in other embodiments, the material may comprise a ceramic material, glass material and/or the like.

The amplifier system 16 may comprise a further frame 45. The frame 28 may be connected to or mounted on the further frame 45. For example, the frame 28 may be welded to the further frame 45 or at least a part thereof. In other embodiments, the frame and further frame may be integral. The frame 28 may be mounted or connected to the further frame such that the frame 28 extends along at least a part of the further frame 45.

The further frame 45 may be configured to mount the optical amplifiers 24a-24d, e.g. in series. For example, the further frame 45 may comprise a plurality of further supporting elements 46a, 46b, eight of which are shown in FIGS. 14A and 14B. It will be appreciated that in other embodiments the further frame may comprise more or less than eight further supporting elements and/or may be configured to mount the amplifiers in a different arrangement.

Each of the further supporting elements 46a, 46b may be configured to protrude or extend from the further frame 45, e.g. towards an interior of the amplifier system 16. Each of the further supporting elements 46a, 46b may be arranged to protrude or extend from the further frame 45 in a direction perpendicular, e.g. substantially perpendicular, to a longitudinal axis B of the further frame 45. For example, each of the further supporting elements 46a, 46b may be arranged to protrude or extend in an upwards direction, e.g. in use of the amplifier system 16.

At least two further supporting element 46a, 46b may be associated with a respective optical amplifier 24. The two further supporting element 46a, 46b may be configured to mount the respective amplifier 46a, 46b. The two further supporting elements 46a, 46b may comprise a different size and/or shape relative to each other. For example, a first supporting element 46a of the two further supporting elements 46a, 46b may comprise or define an L-shape, e.g. substantially L-shape, and/or may be larger than a second supporting element 46b of the two further supporting elements. A second supporting element 46b of the two further supporting elements 46a, 46b may comprise or define a T-shape, e.g. substantially T-shape and/or may be smaller than the first supporting element 46a.

FIG. 14C shows the part of amplifier system 16 shown in FIG. 14B including the optical amplifiers 24a-24d. The two further supporting elements 46a, 46b may be arranged to mount opposite sides, e.g. diagonally opposite sides, of a respective optical amplifier 24.

The amplifier system 16 may comprise a cooling system. The cooling system may be configured to cool at least one or all of the frame and the further frame. For example, the frame 28 and/or the further frame 45 may comprise a plurality of coolant channels (not shown). The coolant channels may be arranged to circulate a coolant through the frame 28 and/or the further frame 45. The coolant may comprise a cooling fluid or liquid, such as water. The coolant channels may be arranged to keep the frame 28 and the further frame 45 at the same temperature. The coolant channels may be arranged so that a temperature across the frame and/or further frame is uniform.

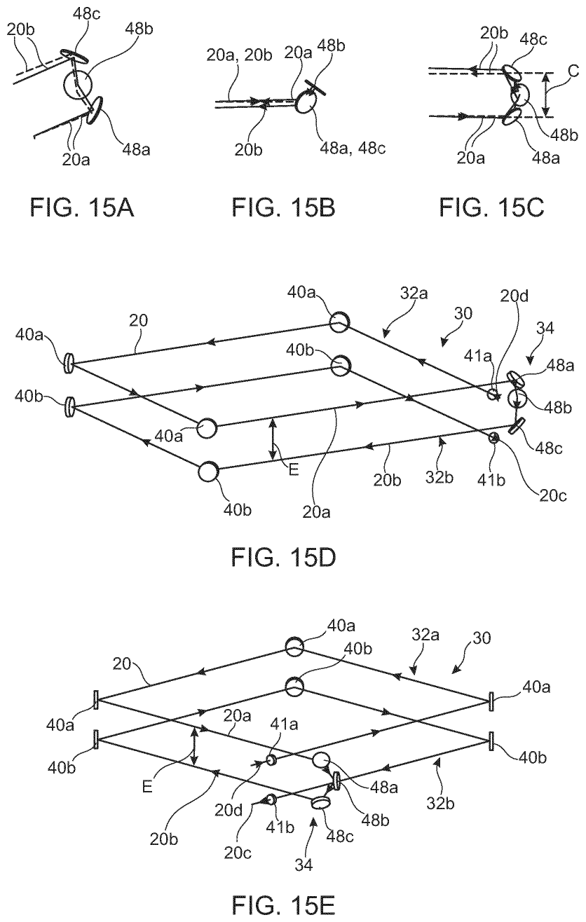

FIGS. 15A to 15C schematically show another exemplary reflector 34 for use in an optical amplifier, such as the optical amplifier 24 shown in FIG. 4. The reflector 34 is provided in the form of the corner cube. The reflector shown in FIGS. 15A to 15C is the same as the reflector 34 described above in relation to FIGS. 5, 11 to 13. As such, any features described above in relation to FIGS. 5, 11 to 13 may also apply to the reflector shown in FIGS. 15A to 15C.

The reflector 34 may comprise one or more reflective surfaces 48a, 48b, 48c, three of which are shown in FIGS. 15A to 15C. It will be appreciated that in other embodiments, the reflector may comprise more or less than three reflective surfaces. In this embodiment, each of the reflective surfaces 48a, 48b, 48c is provided in the form of a planar surface. It will be appreciated that in other embodiments at least one or each of the reflective surfaces may comprise a curved surface.

The reflective surfaces 48a, 48b, 48c may be arranged to be perpendicular, e.g. substantially perpendicular, to each other. In this embodiment, the reflector 34 is configured to reflect the laser beam 20 three times. The incident laser beam 20a may be reflected from the first reflective surface 48a to the second reflective surface 48b. The incident beam 20a may then be reflected from the second reflective surface 48b to the third reflective surface 48c. The third reflective surface 48c may be arranged to reflect the laser beam away from the reflector 34. The reflective surfaces 48a, 48b, 48c may be arranged such that the reflected laser beam 20b is parallel to the incident laser beam 20a. Expressed differently, the reflective surfaces 48a, 48b, 48c may be arranged such that a direction of the reflected laser beam 20b is a reversed direction of the incident laser beam 20a. Although FIGS. 15A to 15C show the first, second and third reflective surfaces as being arranged perpendicularly to each other, it will be appreciated that in other embodiments, the first, second and third reflective surfaces may be differently arranged.

The first, second and third reflective surfaces 48a-48c may be arranged such that an angle of incidence of the laser beam 20 on each of the first, second and third reflective surfaces is the same and equal to about 55.7 degrees. This arrangement of the first, second and third reflective surfaces 48a-48c may be considered as a symmetric arrangement. However, it will be appreciated that in other embodiments, the arrangement of the first, second and third reflective surfaces may be non-symmetric and/or the first, second and third reflective surfaces may be arranged so that the angle of incidence on the first, second and/or third reflective surfaces is different from 55.7 degrees.

The first reflective surface 48a may comprise or define the first position on which the laser beam 20 is incident. The third reflective surface 48c may comprise or define the second position at which the laser beam 20 is reflected away from the reflector 34. The first and second positions of the first and third reflective surfaces 48a, 48c may be spaced from each other. The distance C between the first and second positions on the first and third reflective surfaces 48a, 48c, which is indicated in FIG. 15C, may correspond to the space E between the first and second parts 32a, 32b of the optical path 30, which is indicated in FIG. 3 for the first optical amplifier 24a.

As can be seen in FIGS. 15A to 15C, the second reflective surface 48b is arranged between the first and third reflective surfaces 48a, 48c.

FIGS. 15D and 15E schematically show another exemplary optical path 30 of the laser beam 20 through the optical amplifier 24 shown in FIG. 4 comprising the reflector 34 shown in FIG. 15A to 15C. FIGS. 15D and 15E show the optical path 30, including the first and second optical elements 40a, 40b, first and second optical windows 41a, 41b and the space E between the first and second parts 32a, 32b of the optical path 30. However, the order of the first, second and third reflective surfaces 48a-48c has been reversed in the embodiment shown in FIGS. 15D and 15E relative to the order of the first, second and third reflective elements 48a-48c shown in FIGS. 15A to 15C.

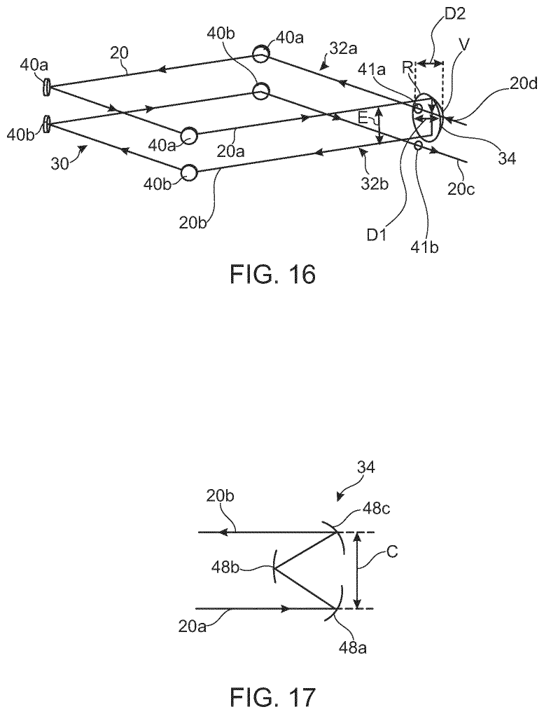

FIG. 16 schematically shows another exemplary reflector 34 for use in an optical amplifier, such as the optical amplifier 24 shown in FIG. 4. The reflector 34 shown in FIG. 16 is similar to the reflector 34 shown in FIGS. 5, 11 to 13 and 15A to 15E. As such, any features described above in relation to FIGS. 5, 11 to 13 and 15A to 15E may also apply to the reflector 34 shown in FIG. 16. Only differences will be described in the following. In the embodiment shown in FIG. 16, the reflector 34 is provided in the form of a retroreflector, such as a conical reflector.

The reflector 34 may be considered as comprising a single reflective surface 48. The reflective surface 48 may be configured such that the reflected laser beam 20b is parallel to the incident laser beam 20a. Expressed differently, the reflective surface 48 may be configured such that a direction of the reflected laser beam 20b is a reversed direction of the incident laser beam 20a. For example, a diameter D1 and/or depth D2 of the reflective surface 48 may be selected such that the reflected laser beam 20b is parallel to the incident laser beam 20a. The depth D2 of the reflective surface 48 may be considered as a distance measured along an axis of symmetry from a vertex V to a plane of a rim R of the reflective surface 48. Although FIG. 16 shows the reflector as comprising a single reflective surface, it will be appreciated that in other embodiments, the reflector may comprise more than one reflective surface.

In the embodiment shown in FIG. 16, the reflective surface 48 may comprise or define the first position on which the laser beam 20 is incident and the second position at which the laser beam 20 is reflected away from the reflector 34. The first and second positions of the reflective surface 48 may be spaced from each other. The distance, which has been omitted from FIG. 16, between the first and second positions of the reflective surfaces 48, may correspond to the space E between the first and second parts 32a, 32b of the optical path 30.

FIG. 17 schematically shows another exemplary reflector 34 for use in an optical amplifier, such as the amplifier 24 shown in FIG. 4. The reflector 34 shown in FIG. 17 is similar to the reflector 34 shown in FIGS. 5, 11 to 13, 15A to 15E and 16. As such, any features described above in relation to FIGS. 5, 11 to 13, 15A to 15E and 16 may also apply to the reflector 34 shown in FIG. 17. Only differences will be described in the following.

In the embodiment shown in FIG. 17, the reflector 34 is configured to reflect the laser beam 20 three times. The reflector 34 may comprise one or more reflective surfaces 48a-48c, three of which are shown in FIG. 17. A first reflective surface 48a may comprise or define the first position on which the laser beam 20 is incident. A third reflective surface 48c may comprise or define the second position at which the laser beam 20 is reflected away from the reflector 34. The first and second positions of the first and third reflective surfaces 48a, 48c may be spaced from each other. The distance C between the first and second positions on the first and third reflective surfaces 48a, 48c, which is indicated in FIG. 17, may correspond to the space E between the first and second parts 32a, 32b of the optical path 30, which is indicated in FIG. 3 for the first optical amplifier 24a.

Each of the first, second and third reflective surfaces 48-48c may comprise or define a curved surface. A curvature of each of the first and third reflective surfaces 48a, 48c and an arrangement of the first and third reflective surfaces 48a, 48c may be selected such that the first and third reflective surfaces 48a, 48c define or lie on a common parabola. For example, the first and third reflective surfaces 48a, 48c may be arranged such that the first and third reflective surfaces 48a, 48c define or lie on a common cone.

The reflective surfaces 48a-48c may be arranged such that the incident laser beam 20a, the reflected laser beam 20b and the path 50 of the laser beam 20 between the first and second positions, e.g. the first and third reflective surfaces 48a, 48c, defines a M-shape, e.g. a substantially M-shape, as shown in FIG. 17. For example, a second reflective surface 48b may be arranged between the first reflective surface 48a and the third reflective surface 48c. The second reflective surface 48b may be arranged to face in a first direction. The first and third reflective surfaces 48a, 48c may be arranged to face in a second direction. The first and second directions may be different and/or opposite, e.g. substantially opposite, to each other. For example, the second reflective surface 48b may be arranged opposite to the common parabola defined by the first and third reflective surfaces 48a, 48c. The reflector 34 shown in FIG. 17 may be considered as defining a cat's eye configuration.

It will be appreciated that the arrangement of the retroreflector is not limited to the embodiments or examples disclosed herein and that in other embodiments, the retroreflector may be differently arranged.

It will be appreciated that the terms “optical amplifier” and “amplifier” may be interchangeably used.

It will be understood that references to a plurality of features may be interchangeably used with references to singular forms of those features, such as for example “at least one” and/or “each”. Singular forms of a feature, such as for example “at least one” or “each,” may be used interchangeably.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the clauses and claims set out below.

### Clauses:

1. An optical amplifier configured to amplify a laser beam, the optical amplifier comprising:
   an optical path of the laser beam, the optical path comprising a first part and a second part; and
   a reflector configured to reflect the laser beam so as to direct the laser beam between the first and second parts of the optical path, the reflector being configured to reflect the laser beam such that the laser beam reflected by the reflector is parallel to the laser beam incident on the reflector.
2. The optical amplifier of clause 1, wherein the reflector is configured to reflect the laser beam at least two times to direct the laser beam between the first and second parts of the optical path.
3. The optical amplifier of clause 1 or 2, wherein the reflector comprises a retroreflector.
4. The optical amplifier of clause 3, wherein the retroreflector comprises at least one of:
   a corner reflector; and
   a conical reflector.
5. The system of clause 4, wherein the corner reflector comprises a corner cube.
6. The optical amplifier of any preceding clause, wherein the reflector comprises one or more reflective surfaces, the one or more reflective surfaces comprising a first position on which the laser beam is incident and a second position at which the laser beam is reflected away from the reflector, at least one or each of the one or more reflective surfaces comprising a planar surface or a curved surface.
7. The optical amplifier of clause 6, wherein the first and second positions of the one or more reflective surfaces are spaced from each other and a distance between the first and second positions of the one or more reflective surfaces corresponds to a space between the first and second parts of the optical path.
8. The optical amplifier of clause 6 or 7, wherein the one or more reflective surfaces are arranged such that the laser beam is reflected at least three times to direct the laser beam between the first and second parts of the optical path, the one or more reflective surfaces being arranged such that at least one of:
   at least one reflective surface is arranged between at least two other reflective surfaces;
   at least one reflective surface is arranged to face in a first direction and at least one other reflective surface is arranged to face in a second direction, the first and second directions being different and/or opposite to each other; and
   the laser beam reflected by the reflector, the laser beam incident on the reflector and/or a path of the laser beam between the first and second positions of the one or more reflective surfaces define an M-shape.
9. An amplifier system for use in a laser system, the system comprising:
   a plurality of optical amplifiers, at least one or each optical amplifier of the plurality of optical amplifier comprising an optical amplifier according to any preceding clause;
   an optical system configured to optically couple at least one of the plurality of optical amplifiers to at least one other of the plurality of optical amplifiers; and
   a frame configured to support the optical system, the frame being configured to be separate from the plurality of optical amplifiers.
10. The system of clause 9, wherein the frame is configured to at least one of:
   support the optical system such that each of the plurality of optical amplifiers is moveable relative to the optical system; and
   support the optical system such that each of the plurality of optical amplifiers is detached from the optical system.
11. The system of any one of clauses 9 to 10, wherein the system comprises a further frame configured to mount the plurality of optical amplifiers, the frame being connected to the further frame or the frame being integral with the further frame.
12. A laser system comprising:
   a laser configured to generate a laser beam; and
   an amplifier system according to any one of clauses 9 to 11, wherein the amplifier system is configured to amplify the laser beam.
13. The laser system of clause 12, wherein the frame is configured to connect to the laser.
14. A radiation system comprising:
   an EUV radiation source; and
   a laser system according to clause 12 or 13.
15. A radiation system comprising:
   an EUV radiation source; and
   a laser system comprising an optical amplifier according to any one of clauses 1 to 8.
16. A lithographic system comprising a radiation system according to clause 14 or 15 and a lithographic system.

1-15. (canceled)

16. An optical amplifier configured to amplify a laser beam, the optical amplifier comprising:
an optical path of the laser beam, the optical path comprising a first part and a second part; and
a reflector configured to reflect the laser beam so as to direct the laser beam between the first and second parts of the optical path, the reflector being configured to reflect the laser beam such that the laser beam reflected by the reflector is parallel to the laser beam incident on the reflector.

17. The optical amplifier of claim 16, wherein the reflector is configured to reflect the laser beam at least two times to direct the laser beam between the first and second parts of the optical path.

18. The optical amplifier of claim 16, wherein the reflector comprises a retroreflector.

19. The optical amplifier of claim 18, wherein the retroreflector comprises at least one of:
a corner reflector, wherein the corner reflector comprises a corner cube; and
a conical reflector.

20. The optical amplifier of claim 16, wherein the reflector comprises one or more reflective surfaces, the one or more reflective surfaces comprising a first position on which the laser beam is incident and a second position at which the laser beam is reflected away from the reflector, at least one or each of the one or more reflective surfaces comprising a planar surface or a curved surface.

21. The optical amplifier of claim 20, wherein the first and second positions of the one or more reflective surfaces are spaced from each other and a distance between the first and second positions of the one or more reflective surfaces corresponds to a space between the first and second parts of the optical path.

22. The optical amplifier of claim 20, wherein the one or more reflective surfaces are arranged such that the laser beam is reflected at least three times to direct the laser beam between the first and second parts of the optical path, the one or more reflective surfaces being arranged such that at least one of:
at least one reflective surface is arranged between at least two other reflective surfaces;
at least one reflective surface is arranged to face in a first direction and at least one other reflective surface is arranged to face in a second direction, the first and second directions being different and/or opposite to each other; and
the laser beam reflected by the reflector, the laser beam incident on the reflector and/or a path of the laser beam between the first and second positions of the one or more reflective surfaces define an M-shape.

23. An amplifier system for use in a laser system, the system comprising:
a plurality of optical amplifiers, at least one or each optical amplifier of the plurality of optical amplifiers comprising the optical amplifier of claim 16;
an optical system configured to optically couple at least one of the plurality of optical amplifiers to at least one other of the plurality of optical amplifiers; and
a frame configured to support the optical system, the frame being configured to be separate from the plurality of optical amplifiers.

24. The system of claim 23, wherein the frame is configured to at least one of:
support the optical system such that each of the plurality of optical amplifiers is moveable relative to the optical system; and
support the optical system such that each of the plurality of optical amplifiers is detached from the optical system.

25. The system of claim 23, further comprising a further frame configured to mount the plurality of optical amplifiers, the frame being connected to the further frame or the frame being integral with the further frame.

26. A laser system comprising:
a laser configured to generate a laser beam; and
an amplifier system configured to be used in the laser system, the amplifier system comprising a plurality of optical amplifiers, at least one or each optical amplifier of the plurality of optical amplifiers comprising the optical amplifier of claim 16;
an optical system configured to optically couple at least one of the plurality of optical amplifiers to at least one other of the plurality of optical amplifiers; and
a frame configured to support the optical system, the frame being configured to be separate from the plurality of optical amplifiers, wherein the amplifier system is configured to amplify the laser beam.

27. The laser system of claim 26, wherein the frame is configured to connect to the laser.

28. A radiation system comprising:
an EUV radiation source; and
the laser system of claim 26.

29. A radiation system comprising:
an EUV radiation source; and
the laser system comprising an optical amplifier of claim 16.

30. A lithographic system comprising:
the radiation system of claim 28; and
a lithographic system.
